(19) United States
(12) Patent Application Publication
(10) Pub. No.: US 2006/0105552 A1
(43) Pub. Date: May 18, 2006

(54) Apparatus and method of activating impurity atom in manufacture of semiconductor device

(76) Inventor: Jun-Seuck Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/258,208

(22) Filed: Oct. 26, 2005

(30) Foreign Application Priority Data
Nov. 18, 2004 (KR) 2004-94483

(51) Int. Cl. H01L 21/265

(52) U.S. Cl. 438/522

(57) ABSTRACT

An apparatus and a method of activating an impurity atom doped into a semiconductor material use of a resonant principle. Impurity atoms are doped into the semiconductor material, and microwaves having the same frequency as a natural frequency of vibration of the impurity are applied to the semiconductor material. The intensity of the vibrations of the impurity atom is increased by the resonant principle. Thus, a mean free path of the impurity atom is extended, so that the impurity atoms combine with a substance constituting the semiconductor material to create a carrier (free electrons or holes). Accordingly, only the impurity atoms in the region doped with the impurity are selectively activated, preventing the impurity from undesirably being introduced into another region, thereby improving an operating characteristic of the device.

### CROSS-REFERENCE TO RELATED APPLICATION

This application claims the benefit of Korean Patent Application No. 10-2004-0094483, filed Nov. 18, 2004, the entirety of which is hereby incorporated herein by reference for all purposes as if fully set forth herein.

### BACKGROUND OF THE INVENTION

1. Technical Field

The present invention relates to manufacture of a semiconductor device, and, more particularly, to an apparatus and a method of selectively activating impurity atoms by use of a resonance principle.

2. Discussion of Related Art

In general, a semiconductor device is manufactured by depositing and patterning a thin film for performing various functions on an upper surface of a substrate, which forms various circuit geometric structures. A process of manufacturing the semiconductor device includes: a deposition process of forming a processing film on the semiconductor substrate, an etching process (i.e., photolithography) of applying a photosensitive film on the processing film formed by the deposition process, exposing the photosensitive film using a mask, and patterning the processing film by use of the photosensitive film as an etching mask; and a chemical mechanical polishing (CMP) process of depositing an interlayer insulation film on the semiconductor substrate, and collectively polishing the entire surface of the semiconductor substrate to remove a stepped portion.

Recently, the semiconductor device has been significantly developed with the rapid development of the telecommunication field and the rapid popularization of information media. Hence, since the semiconductor device functionally needs to have a mass storage capacity, as well as high speed operation, the degree of integration for the semiconductor device is in fact gradually increased. In the manufacture of the semiconductor device using these processes as described above, however, an aspect ratio of adjacent patterns is increased due to the high degree of integration of the semiconductor device. As a result, step coverage is inferior when a material layer is deposited between regions. Also, the patterning process, such as etching, does not proceed accurately due to step height differences between of the patterns formed previously, which deteriorates the reliability and productivity of the semiconductor device.

Thus, in the course of high integration to increase the mass storage capability of the semiconductor device, respective unit elements forming a memory cell are scaled down. A high integration technique forming a multilayered structure in a limited area is remarkably developed. As one example of the methods for manufacturing the semiconductor device by use of the multilayered structure, a double layered structure is employed, in which plural metal layers are formed in the semiconductor device and the respective metal layers are connected by a via contact. FIG. 1 shows a transistor structure to which a conventional double layer process is applied.

Referring to FIG. 1, a source region 14 and a drain region 15 are formed in a p-type semiconductor substrate 10, and a gate electrode 12 of a gate region is formed on the semiconductor substrate 10. In this case, even though not shown in the drawing, a gate insulating layer composed of an insulating material, such as an oxide film, is formed under the gate electrode 12.

A first metal layer 18 functioning as a word line is formed on the gate electrode 12, and the first metal layer 18 is connected to the gate electrode 12 via a contact 16. The first metal layer 18 is connected to a second metal layer 22 by a via contact 20. In view of characteristics of a circuit design and a layout design, after the gate electrode 12 and the first metal layer 18 are connected to each other via the contact 16, the via contact 20 is formed on the first metal layer 18. Then, a second metal layer 22 contacting the via contact 20 is formed, so that the first metal layer 18 and the second metal layer 22 are connected to each other. In this case, the first metal layer 18 and the contact 16, and the second metal layer 22 and the via contact 20 may be formed through a damascene process forming a contact and a metal layer at the same time, or through a typical contact forming method in which a contact is formed and then a metal layer is formed on the metal layer.

FIG. 2 shows another example of a double layer process applied in view of a reduced design rule of a semiconductor device, and illustrates a laminated transistor structure in which an n-MOS transistor and a p-MOS transistor are formed on the same vertical line above a semiconductor substrate.

Referring to FIG. 2, an isolation layer 102 is formed on a p-type semiconductor substrate 100 doped with a Group III impurity through a conventional shallow trench isolation (STI) process. A gate electrode 104 of an n-MOS transistor is formed on an active region defined by the isolation layer 102. In this case, n-type source and drain regions doped with a Group V impurity are formed under a side wall of the gate electrode 104, which are not shown. An n-type epitaxial semiconductor layer 106 is formed on the semiconductor substrate 100 with the gate electrode 104 of the n-MOS transistor formed thereon. A gate electrode 108 of a p-MOS transistor is formed on the epitaxial layer 106. Although not shown, p-type source and drain regions doped with Group III impurity are formed in the epitaxial layer 106 under a side wall of the gate electrode 108 of the p-MOS transistor.

As shown in FIG. 2, in view of the reduced design rule of the semiconductor device, the method of forming the p-MOS transistor on a vertical line of the n-MOS transistor is widely applied in the art. In formation of the transistor having the layered structure as described above, however, an impurity, in particular, boron, to be implanted to form the source and drain regions of the p-MOS transistor has a heat sensitive characteristic. In the transistor having the stacked structure shown in FIG. 2, infiltration of the boron atoms into another region or regions due to heat is minimized by forming the n-MOS transistor and then forming the p-MOS transistor. When a multilayered structure having more than two layers is formed to satisfy the design rule of a further integrated semiconductor device, a rapid thermal annealing (RTA) process has to be carried out more frequently. The doped boron frequently infiltrates into another region or regions through the RTA process. Specifically, in the RTA process, the semiconductor substrate is loaded in a heat chamber, and then the semiconductor substrate is annealed. Since the heat is applied to the overall surface of the semiconductor substrate, the boron doped into one region may infiltrate into one or more other regions. There is a problem in that if the boron infiltrates into other regions that form the source and drain regions of the p-MOS transistor, an electrical characteristic of the semiconductor device is deteriorated.

The reason why the RTA process is carried out in a typical process of manufacturing the semiconductor device is to form free electrons and holes by using an impurity atom implanted into the material film. A principle thereof will be described in detail with reference to FIGS. 3 through 7.

FIGS. 3 through 5 illustrate the process in which implanted impurities are recombined into a new crystal structure after the implanted impurities are annealed.

Referring to FIG. 3, silicon (Si) 200 is an atom having four valence electrons which covalent bond to four adjacent silicon atoms to form silicon crystallization. If an impurity, i.e., B 202, is implanted into the silicon crystallization, the covalent bond of the silicon lattice is broken by acceleration energy of the implanted B, as shown in FIG. 4, creating an amorphous state. Hence, implanted B atoms are stuck between silicon atoms.

If the silicon crystallization of which the silicon is locally amorphized by the impurity atoms is subjected to the annealing process, the amorphized silicon lattices are recombined with the impurity atoms to form free electrons or holes.

The principle of forming free electrons or holes by implementing the annealing process will now be described with reference to FIGS. 6 through 10.

FIG. 6 illustrates an energy level of intrinsic semiconductor. The term intrinsic semiconductor means a perfect semiconductor crystal free of impurity or crystal defects. A valence band Ev of the intrinsic semiconductor is filled with electrons 200, while a conduction band Ec is empty. When the intrinsic semiconductor is subjected to the RTA process to apply high temperature to the semiconductor, electrons of the valence band are excited thermally, and then move across an energy band gap Eg to the conduction band, Ec. Specifically, for silicon, Eg is about 1.1 eV. The electrons of the valence bond Ev move across the energy band of 1.1 eV to the conduction band Ec to generate electron-hole pairs. These electron-hole pairs are the only charge carriers in the intrinsic semiconductor.

FIGS. 7 through 10 illustrate the energy level of extrinsic semiconductor. The term extrinsic semiconductor means an intrinsic semiconductor, which has the energy band characteristic shown in FIG. 6, which is doped with an impurity. Conductivity of the semiconductor is changed due to the doped impurity. If a Group III impurity is doped, carriers mostly form holes in the p-type semiconductor, while if a Group V impurity is doped, carriers mostly form electrons in the n-type semiconductor.

FIGS. 7 and 8 illustrate an energy band of extrinsic semiconductor in the case where a quinquevalent impurity in Group V (P, As, Sb, etc.) is doped. Referring to FIG. 7, the valence band Ev is filled with electrons 302, while the conduction band Ec is empty. An additional energy level, i.e., donor level Ed, is formed under the conduction band Ec. The donor level Ed is filled with electrons 304 at 0 K, and very little thermal energy is required to excite the electrons in the donor level Ed to the conduction band Ec. Specifically, as shown in FIG. 8, if the temperature is raised to about 50° K, the electrons 304 in the donor level Ed are easily donated to the conduction band Ec. The reason for this is because the energy band is decreased relative to the intrinsic semiconductor. For example, by doping the intrinsic semiconductor with any one of quinquevalent impurities, As, the energy band is Ec−Ed=0.049 eV. Accordingly, in the case of the intrinsic semiconductor composed of silicon, 1.1 eV energy is required such that electric current flows by exciting the electrons from the valence band to the conduction band. In the case of the extrinsic semiconductor doped with quinquevalent impurities, however, the electric current flows such that the electrons in the donor level is easily excited to the conduction band by only 0.049 eV.

FIGS. 9 and 10 illustrate an energy band of extrinsic semiconductor in the case where a trivalent impurity in Group III (B, Al, Ga, In, etc.) is doped. Referring to FIG. 9, the valence band Ev is filled with electrons 306, while the conduction band Ec is empty. An additional energy level, i.e., acceptor level Ea, is formed above the valence band Ev. The acceptor level is empty at 0 K. As shown in FIG. 10, if the temperature is raised to about 50 K, the electrons 306 in the valence band are easily excited to the acceptor level, thereby creating holes 308 in the valence band. The reason is because the energy band is decreased relative to the intrinsic semiconductor. For example, by doping the intrinsic semiconductor with any one of trivalent impurities, B, the energy band is Ea−Ev=0.045 eV. Accordingly, 0.045 eV energy is required such that electric current easily flows by exciting the electrons from the valence band to the acceptor level. This is much lower than the energy required for intrinsic semiconductor.

Hence, if the extrinsic semiconductor is formed by doping the intrinsic semiconductor made of silicon with impurities, the energy band Eg is decreased to Ec−Ed (in case of implanting quinquevalent impurity) or Ea−Ev (in case of implanting trivalent impurity), thereby facilitating the flow of electric current through transfer of the carrier (free electrons or holes).

A conventional RTA process applied to excite the electrons is an annealing process which is implemented after loading the semiconductor substrate in a hot chamber. Hence, the heat is applied to the overall surface of the semiconductor substrate. If the RTA process is repeatedly implemented, the doped impurities may be introduced into other regions. In the case where the impurity is introduced into one or more other regions, the reliability of the transistor is lowered, and the productivity of the semiconductor device is also reduced. Consequently, required is a technique for electively activating the doped impurity atom by annealing not the overall surface of the semiconductor substrate but only the region doped with impurity.

### SUMMARY OF THE INVENTION

The present invention is directed to provide an apparatus and a method of activating impurity atom, which can overcome one or more of the disadvantages mentioned above.

In accordance with one aspect of the present invention, an impurity atom activating apparatus for use in manufacture of a semiconductor device, includes a susceptor disposed in a process chamber, a wafer doped with an impurity atom having a natural frequency of vibration being loaded on the susceptor; a gas inlet port formed at one side of the process chamber for introducing a gas containing the impurity atom having the natural frequency of vibration; a gas outlet port for discharging the gas introduced through the gas inlet port; and a microwave generating unit for applying a microwave having the same frequency of vibration as the natural frequency of vibration of the impurity atom to the semiconductor substrate doped with the impurity atom to increase the natural frequency of vibration of the impurity atom and thereby to combine the impurity atom with a substance constituting the semiconductor substrate.

According to another aspect of the present invention, an impurity atom activating method for use in manufacture of a semiconductor device, includes implanting an impurity atom having a natural frequency of vibration into a semiconductor substrate; and applying a microwave having the same frequency of vibration as the natural frequency of vibration of the impurity atom to the semiconductor substrate doped with the impurity atom to increase the natural frequency of vibration of the impurity atom and thereby to combine the impurity atom with a substance constituting the semiconductor substrate.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a cross sectional view illustrating a transistor structure to which a conventional double layer process is applied;

FIG. 2 is a cross-sectional view of another example of another conventional double layer process, showing a laminated transistor structure in which transistors having contrary operating characteristics are formed on the same vertical line above a semiconductor substrate;

FIGS. 3 through 5 are views illustrating a process in which implanted impurities are recombined into a new crystal structure after annealing;

FIG. 6 is a view illustrating an energy level of intrinsic semiconductor;

FIGS. 7 through 10 are views illustrating an energy level of extrinsic semiconductor;

FIG. 11 is a cross-sectional view illustrating an impurity atom activating apparatus equipped with a microwave generator;

FIG. 12 is a view explaining a process of activating impurity atom according to a first embodiment; and

FIG. 13 is a view explaining a process of activating impurity atoms according to a second embodiment.

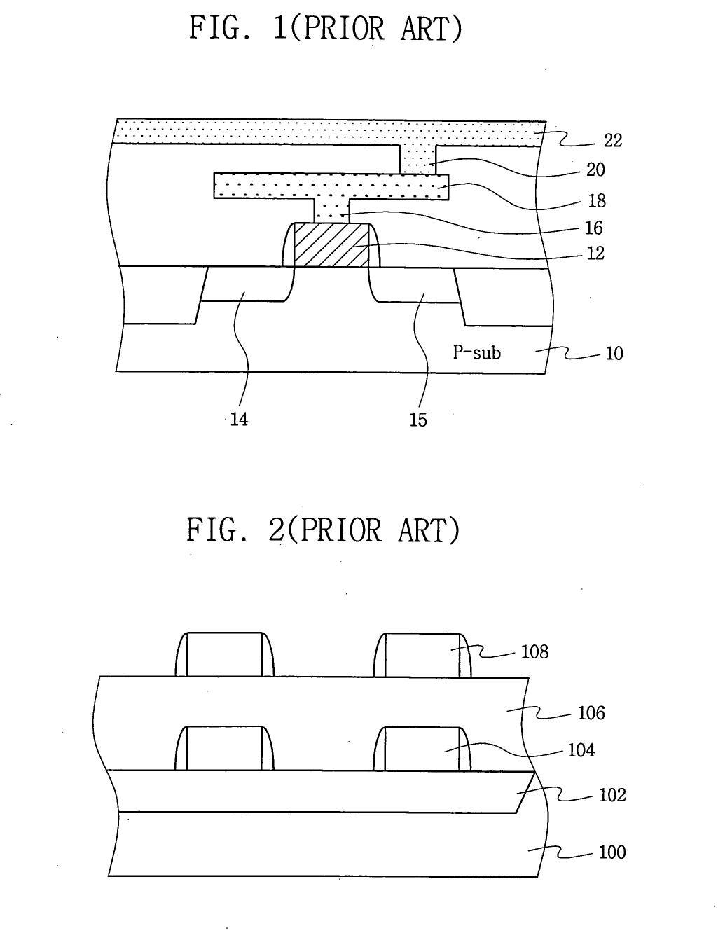

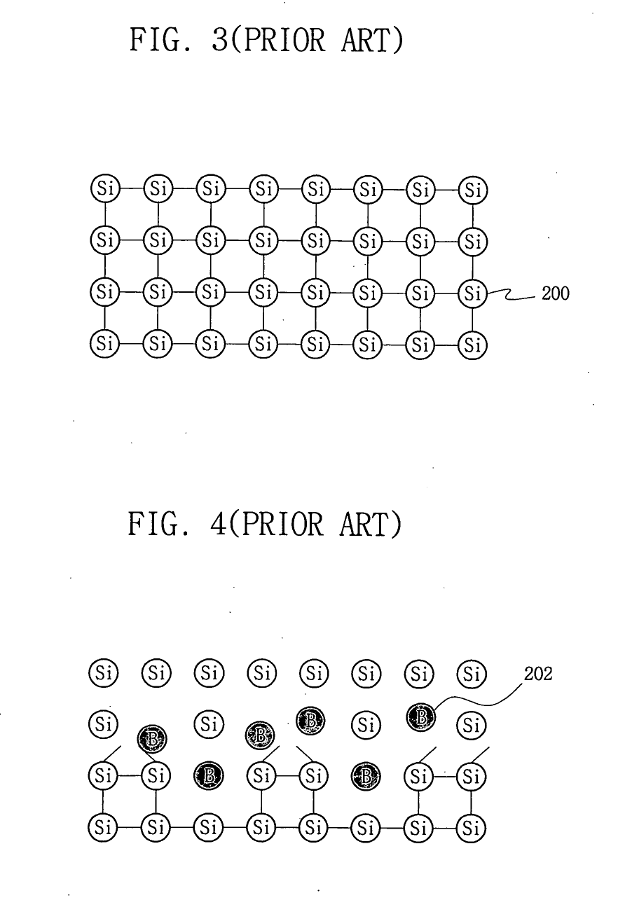

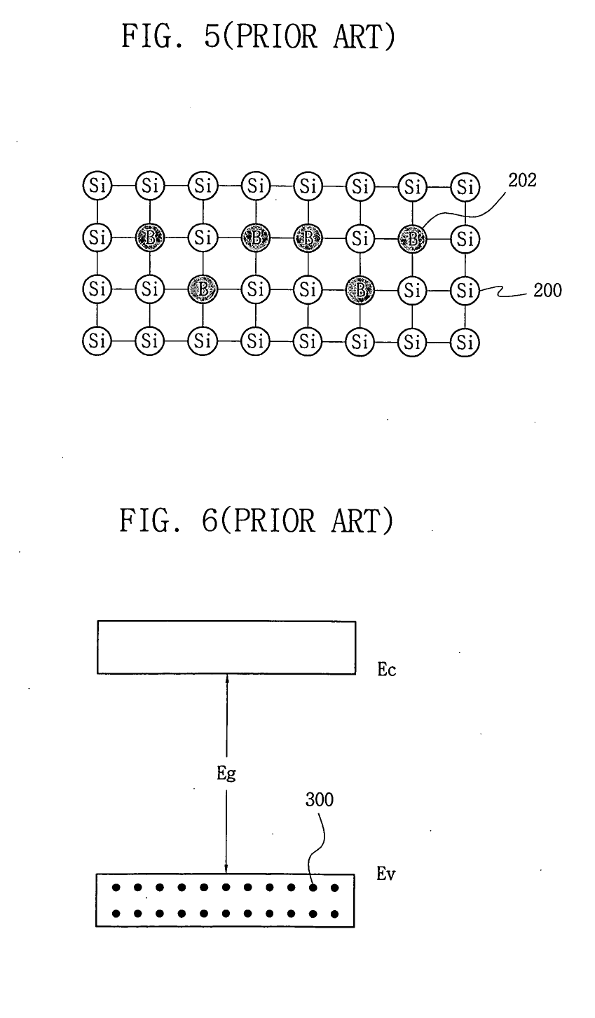

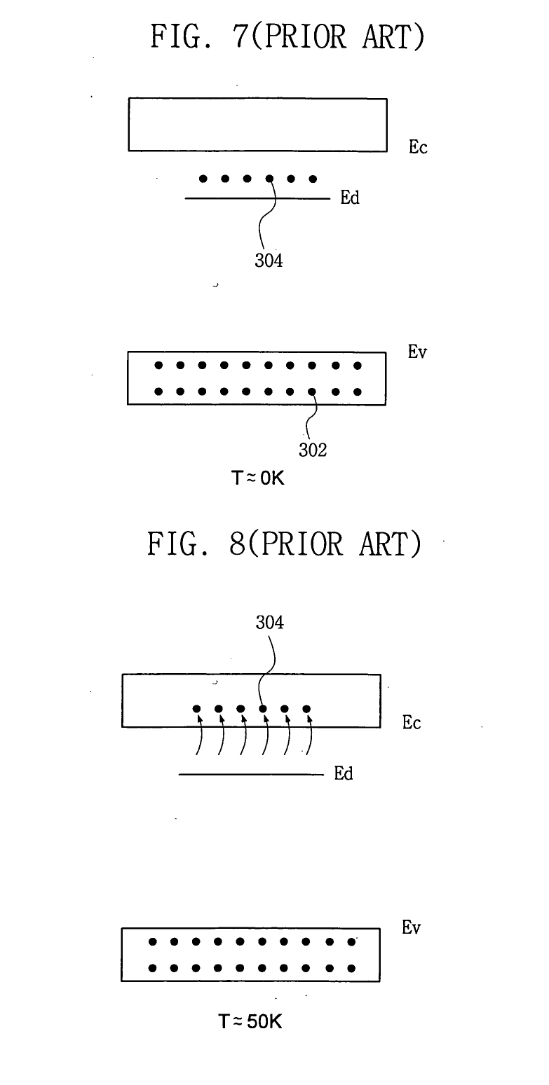

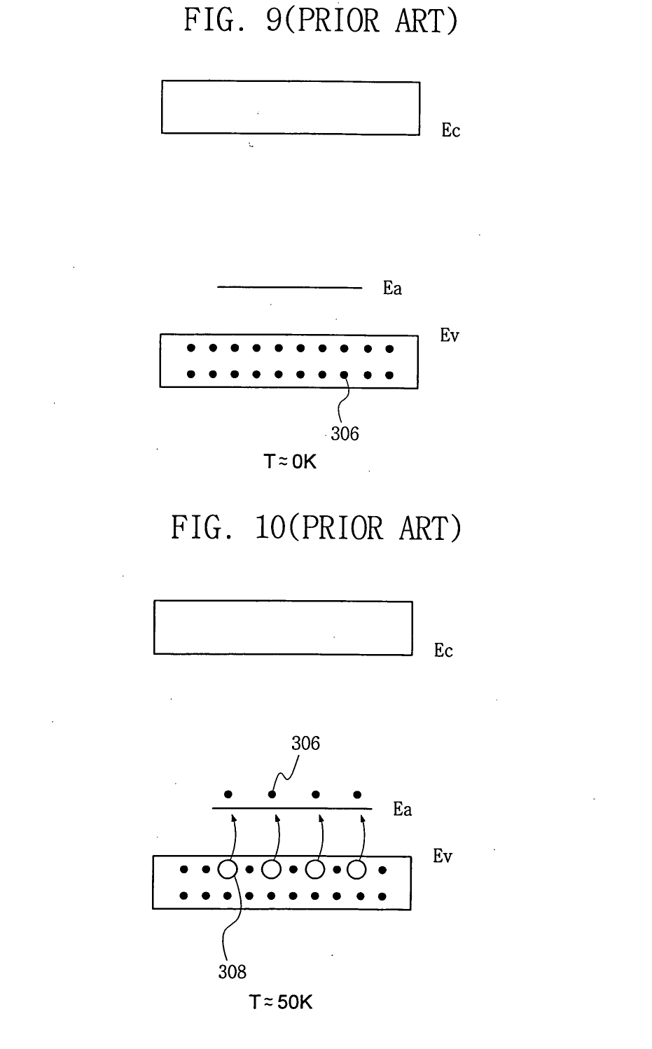

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided as teaching examples of the invention. Like numbers refer to like elements.

In general, particles constituting a substance vibrate constantly, and these vibrating particles have a natural frequency of vibration. If microwaves having a frequency similar to the natural frequency of vibration of the particles are applied to the vibrating particles, the intensity of vibration of the particles is increased, which may be explained based on a resonant phenomenon. The term “resonant phenomenon” means that in the case where an external force is applied to the weight of a pendulum which moves from side to side, when a frequency of vibration of the external force coincides with a natural frequency of vibration of the pendulum vibrating from side to side (frequency of vibration when resistance is zero), the pendulum swings more forcefully.

After a silicon substrate is doped with an impurity, such as B or AS, to manufacture a semiconductor device, when microwaves having the same frequency as a natural frequency of vibration of the impurity are applied to the substrate, a mean free path of the implanted impurity is extended, thereby increasing the possibility of combining the impurity with a silicon atom. This yields the same result as of the case where after the impurity is implanted into the silicon substrate and then the substrate is subjected to annealing, such as rapid thermal annealing (RTA). Specifically, the RTA process is performed to increase a momentum of a doped impurity, and the process using the resonant phenomenon is performed to increase the intensity of vibration of the impurity by applying the microwaves having the same frequency as the natural frequency of vibration of the impurity. As a result, both the RTA process and the process using the resonant phenomenon activate the doped impurity to create a desired carrier.

A conventional annealing process (for example, RTA) has a drawback of adversely affecting the semiconductor device. That is, the RTA process to activate the impurity is an annealing process implemented in a hot chamber, which applies the heat to the overall surface of the semiconductor substrate. Hence, the impurity doped into a material film is likely to be introduced into another region or regions. In the case where the impurity restrictedly implanted into any region to manufacture a transistor is undesirably introduced into another region or regions, the operating characteristic of the transistor is unstable.

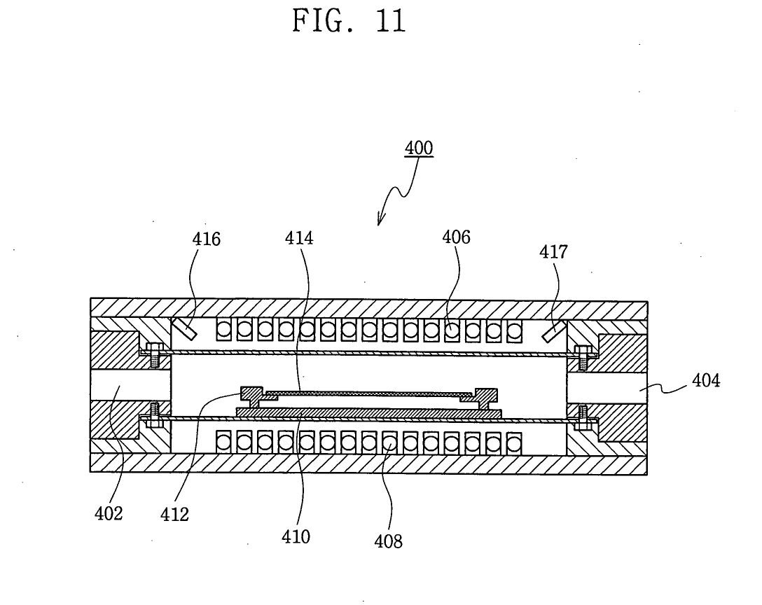

In order to solve the problem of the prior art caused by the RTA process, but to achieve the same effect as the RTA process, therefore, a new method of activating the impurity atom by use of the resonant principle as described above is devised. FIG. 11 is a cross-sectional view illustrating an impurity atom activating apparatus 400 equipped with a microwave generator according to one embodiment.

Referring to FIG. 11, the apparatus 400 includes a gas inlet port 402 for introducing a gas containing impurity atom, and a gas outlet port 404 for discharging the gas introduced into a chamber through gas inlet port 402. The chamber is provided with an upper lamp 406 and a lower lamp 408 that can raise a temperature in the chamber. A substrate 414 to be processed is loaded on a susceptor 410, and is supported by a support ring 412 installed on susceptor 410. Apparatus 400 also includes microwave generating units 416 and 417 disposed at an upper portion of the chamber for applying microwaves to a surface of substrate 414. FIG. 11 illustrates microwave generating units 416, 417 disposed at both upper sides in the chamber, but only one microwave generating unit, or more than two microwave generating units, may be provided, if necessary.

The substrate 414 includes at least one semiconductor material into which an impurity is implanted. Beneficially, the substrate 414 may be a semiconductor substrate in which case the semiconductor material may comprise the base material of the substrate 414, itself. Additionally or alternatively, the substrate 414 may include an epitaxial semiconductor layer into which an impurity is implanted. For example, one impurity may be implanted into the base semiconductor material of substrate 414, while another impurity is implanted into a separate semiconductor layer formed on the base material of the substrate 414 (e.g., see FIG. 2).

Beneficially, the apparatus 400 may implant the one or more impurities into a semiconductor material of substrate 414 using a gas provided through gas inlet port 402. Alternatively, one or more impurities may be implanted into a semiconductor material of substrate 414 in a separate process chamber.

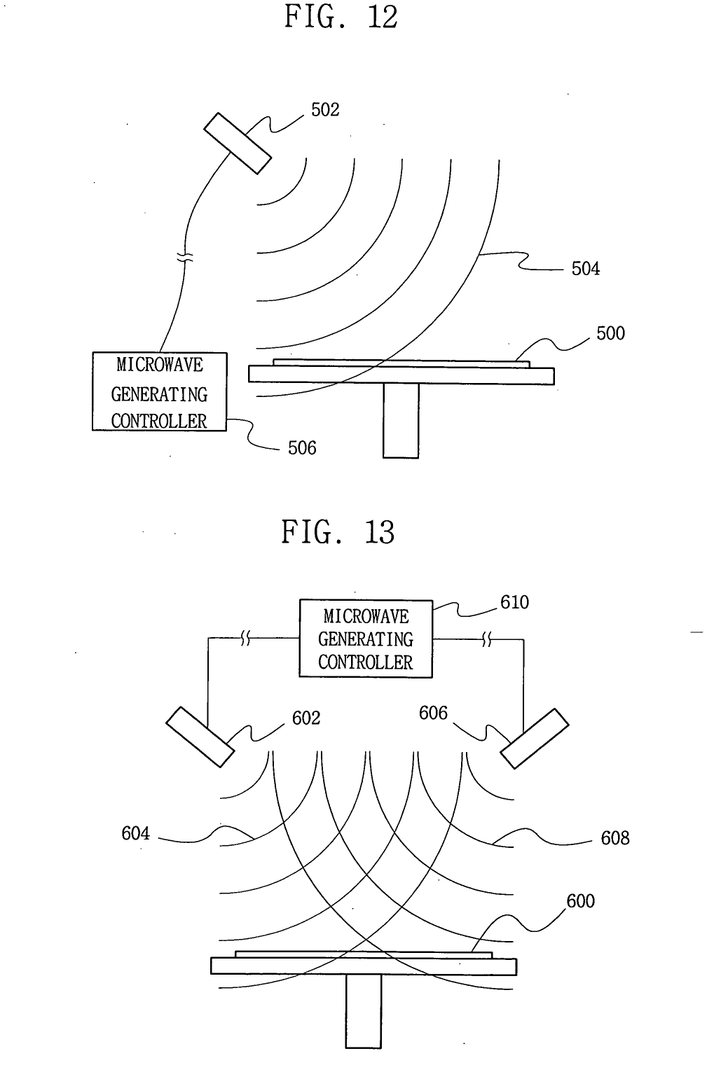

In order to activate the impurity atom in the substrate 414, apparatus 400 employs the microwaves generated from microwave generating units 416 and 417. Hence, it can minimize introduction of the activated impurity atom into one or more other regions besides the desired implanted region. A process of activating the impurity atom will now be described in detail with reference to FIGS. 12 and 13.

Referring to FIG. 12, a substrate 500 having a semiconductor material doped with an impurity is disposed in the chamber. The semiconductor material may be composed of silicon Si, germanium Ge, or gallium arsenide GaAs, and the impurity doped into the semiconductor material may be a Group III element, such as B, Al, Ga, In, etc., or a Group V element, such as P, As, Sb, etc.

The microwave generating unit 502 is disposed above the substrate 500, so as to apply microwaves 504, which have the same frequency as the natural frequency of vibration of the impurity atom doped into the semiconductor material. In this case, microwave generating unit 502 is controlled by a microwave generating controller 506.

When the microwaves 504 are applied to the semiconductor substrate 500, the intensity of vibrations of the impurity implanted into the semiconductor material is increased by the microwaves 504 having the same frequency as the natural frequency of vibration of the impurity itself, thereby extending the mean free path. According to the extended mean free path of the implanted impurity, the possibility of combining the impurity with the substance (for example, silicon atoms) constituting the semiconductor material may be increased. In the case of a silicon material, the activated impurity atoms combine with the silicon atoms to create the wanted carriers. Specifically, if the impurity implanted into the semiconductor substrate made of silicon is a Group III element, it creates holes, while if the impurity is a Group V element, it creates free electrons.

FIG. 12 illustrates an apparatus and method of activating an impurity atom in the case where either one of a Group III or V element is doped into the semiconductor material, but FIG. 13 illustrates an apparatus for activating the impurity atoms in the case where at least two elements from Group III and/or Groups V are doped into one ore more semiconductor materials.

Referring to FIG. 13, a substrate 600 having one or more semiconductor materials (e.g., silicon Si, germanium Ge, or gallium arsenide GaAs) is doped with one or more Group III elements (e.g., B) and/or Group V elements (e.g., As). A first microwave generating unit 602 for generating microwaves 604 having the same frequency as a natural frequency of vibration of B, and a second microwave generating unit 606 for generating microwaves 608 having the same frequency of vibration as a natural frequency of vibration of As, are disposed above substrate 600. In this case, microwave generating units 602 and 606 are controlled by a microwave generating controller 610. In order to increase the intensity of vibration of B and As, the microwaves may be simultaneously or alternatively generated by control of the microwave generating controller 610. In general, in the case of implanting at least two impurities, microwave generating units for generating microwaves corresponding to the natural frequencies of vibration of the implanted purities may be disposed above a substrate, and may be controlled by microwave generating controller 610.

When microwaves 604, 608 having the same frequencies of vibration as natural frequencies of vibration of B and As are applied to substrate 600, the intensities of vibration of B and As implanted into substrate 600 are each increased, thereby extending the mean free path of B and As. According to the extended mean free path of B and As implanted into substrate 600, the possibility of combining the impurities with the substance (for example, silicon atoms) constituting the semiconductor material(s) may be increased. As a result, a B atom activated by microwave generating unit 602 combines with an Si atom to create holes, and an As atom activated by microwave generating unit 606 combines with an Si atom to create free electrons.

As described above, a mean free path of a specific impurity atom implanted into a semiconductor material is extended by use of a resonant principle, so as to easily combine the impurity atom with a substance constituting the semiconductor material and thereby to create a desired carrier. The resonant principle generates microwaves having the same frequency as a natural frequency of vibration of the impurity atom to increase the intensity of vibration of the impurity atom. This contrasts with a conventional annealing process carried out on the entire surface of the semiconductor substrate (RAT process). As a result, the resonant activation process can minimize the introduction of the impurity into an undesired region or regions. The impurity atom activating method employing the resonant principle may be applied to a current method of manufacturing the semiconductor device to be more highly integrated, which can meet the reliability and productivity of the semiconductor device, as well as the design rule thereof.

With the above description, after a Group III or V impurity atom is doped into a semiconductor material, microwaves having the same frequency of vibration as a natural frequency of vibration of the impurity are applied to the semiconductor material. The intensity of vibration of the impurity atom doped into the semiconductor substrate is abruptly increased by the microwaves, and thus a mean free path of the impurity atom is extended, so that the impurity atom combines with a substance constituting the semiconductor material to create a carrier. This method can selectively activate only the impurity atoms in the region doped with the impurity, thereby preventing the impurity doped into any region from being introduced into another region, thus improving the reliability and productivity of the semiconductor device.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A method of forming at least one doped region of a semiconductor device, comprising:
implanting into a semiconductor material of the semiconductor device a first impurity atom having a natural frequency of vibration; and
applying first microwaves to the semiconductor material, wherein the first microwaves have a same frequency as the natural frequency of vibration of the first impurity atom, the first microwaves increasing an intensity of vibration of the first impurity atom to combine the first impurity atom with a substance constituting the semiconductor material.

2. The method of claim 1, wherein the semiconductor material includes any one of Si, Ge, and GaAs.

3. The method of claim 1, wherein the semiconductor material comprises a base material of a semiconductor substrate.

4. The method of claim 1, wherein the semiconductor material comprises a semiconductor layer formed on a substrate.

5. The method of claim 1, wherein the first impurity atom is a Group III element of the periodic table.

6. The method of claim 1, wherein the first impurity atom is a Group V element of the periodic table.

7. The method of claim 1, further comprising:
implanting into the semiconductor material a second impurity atom having a natural frequency of vibration different from the natural frequency of vibration of the first impurity atom; and
applying second microwaves to the semiconductor material, wherein the second microwaves have a same frequency as the natural frequency of vibration of the second impurity atom, the second microwaves increasing an intensity of vibration of the second impurity atom to combine the second impurity atom with the substance constituting the semiconductor material.

8. The method of claim 7, wherein the first and second microwaves are applied simultaneously.

9. The method of claim 8, wherein the first and second microwaves are applied sequentially.

10. The method of claim 7, further comprising:
implanting into a second semiconductor material of the semiconductor device a second impurity atom having a natural frequency of vibration different from the natural frequency of vibration of the first impurity atom; and
applying second microwaves to the second semiconductor material, wherein the second microwaves have a same frequency as the natural frequency of vibration of the second impurity atom, the second microwaves increasing an intensity of vibration of the second impurity atom to combine the second impurity atom with a substance constituting the second semiconductor material.

11. The method of claim 10, wherein the first and second microwaves are applied simultaneously.

12. The method of claim 10, wherein the first and second microwaves are applied sequentially.

13. An apparatus for activating an impurity atom implanted into a semiconductor material of a substrate, the apparatus comprising:
a susceptor disposed in a process chamber and adapted to have the substrate disposed above the susceptor;
a gas inlet port adapted to introduce into the chamber a gas containing the impurity atom;
a gas outlet port adapted to discharge the gas introduced through the gas inlet port; and
a microwave generating unit adapted to apply microwaves to the semiconductor material having the implanted impurity atom, the microwaves having a same frequency as a natural frequency of vibration of the impurity atom to increase an intensity of vibration of the impurity atom to combine the impurity atom with a substance constituting the semiconductor material.

14. The apparatus of claim 13, further comprising a microwave generating controller connected to the microwave generating unit for controlling operation of the microwave generating unit.

15. The apparatus of claim 13, wherein the microwaves have a same frequency as a frequency of vibration of a Group III element of the periodic table.

16. The apparatus of claim 13, wherein the microwaves have a same frequency as a frequency of vibration of a Group V element of the periodic table.

17. An apparatus comprising:
a susceptor disposed in a process chamber;
a gas inlet port adapted to introduce a gas into a process chamber;
a gas outlet port adapted to discharge from the process chamber the gas introduced through the gas inlet port; and
a microwave generating unit adapted to generate first microwaves within the process chamber, the first microwaves having a first frequency, wherein the first frequency is the same as a natural frequency of vibration of at least one of a Group III or Group V element of the periodic table.

18. The apparatus of claim 17, further comprising a second microwave generating unit adapted to generate second microwaves having a second frequency different from the first frequency, wherein the second frequency is the same as a natural frequency of vibration of another one of a Group III or Group V element of the periodic table.

19. The apparatus of claim 18, wherein the first frequency is the same as a natural frequency of vibration of at least one of the Group III elements of the periodic table, and the second frequency is the same as a natural frequency of vibration of at least one of the Group V elements.

20. The apparatus of claim 18, further comprising a microwave generating controller connected to the first and second microwave generating units for controlling operation of the first and second microwave generating units, wherein the microwave generating controller controls the first and second microwave generating unit to selectively output one of the first microwaves and the second microwaves at a time.

21. The apparatus of claim 18, further comprising a microwave generating controller connected to the first and second microwave generating units for controlling operation of the first and second microwave generating units, wherein the microwave generating controller controls the first and second microwave generating unit to simultaneously output the first second microwaves.
